(19) United States
(12) Patent Application Publication
(10) Pub. No.: US 2025/0098076 A1
(43) Pub. Date: Mar. 20, 2025

(54) BOARD AND ELECTRONIC DEVICE

(71) Applicant: KABUSHIKI KAISHA TOSHIBA, Tokyo (JP)

(72) Inventor: Kakeru YAMAGUCHI, Yokohama (JP)

(73) Assignee: KABUSHIKI KAISHA TOSHIBA, Tokyo (JP)

(21) Appl. No.: 18/595,697

(22) Filed: Mar. 5, 2024

(30) Foreign Application Priority Data
Sep. 19, 2023 (JP) 2023-150764

(51) Int. Cl. H05K 3/40; H05K 1/11; H05K 3/34

(52) U.S. Cl. CPC H05K 3/4007; H05K 1/119; H05K 3/3457

(57) ABSTRACT

According to an embodiment, a board includes a base material, a wiring pattern, an insulating member, and a covering portion. The wiring pattern is provided on the base material. The insulating member covers the base material and the wiring pattern, and has an opening corresponding to a bump forming portion of the wiring pattern. The covering portion is formed of a material having a solder contact angle larger than that of the bump forming portion in the opening, and covers a part of the bump forming portion.

### CROSS-REFERENCE TO RELATED APPLICATIONS

This application is based upon and claims the benefit of priority from Japanese Patent Application No. 2023-150764, filed on Sep. 19, 2023; the entire contents of which are incorporated herein by reference.

### FIELD

Embodiments of the present invention relate to a board and an electronic device.

### BACKGROUND

In recent years, a high-density mounting technique corresponding to a large capacity is required for a printed circuit board mounted on a hard disk drive (HDD).

In particular, a flexible printed circuit board (FPC) that electrically connects a magnetic head with a printed circuit board mounted with a control circuit or a drive circuit and is mounted with a preamplifier IC that amplifies a signal from the magnetic head has severe shape restrictions, and thus has increasing mounting difficulties due to an increase in the number of pins and size of the preamplifier IC.

### BRIEF DESCRIPTION OF THE DRAWINGS

FIGS. 1A and 1B are explanatory diagrams of a flexible board assembly for an HDD according to an embodiment;

FIG. 2 is a schematic external perspective view of a solder bump portion;

FIGS. 3A to 3C are explanatory diagrams (part 1) of solder bump formation; and

FIGS. 4A and 4B are explanatory diagrams (part 2) of solder bump formation.

### DETAILED DESCRIPTION

According to an embodiment, a board includes a base material, a wiring pattern, an insulating member, and a covering portion. The wiring pattern is provided on the base material. The insulating member covers the base material and the wiring pattern, and has an opening corresponding to a bump forming portion of the wiring pattern. The covering portion is formed of a material having a solder contact angle larger than that of the bump forming portion in the opening, and covers a part of the bump forming portion.

Next, an embodiment will be described in detail with reference to the drawings.

Prior to describing the embodiment, conventional problems will now be described.

Conventionally, in an HDD, a high-density and highly reliable board is realized by performing optimized design and further verifying reliability.

Meanwhile, a flexible board used in the HDD is mounted with a plurality of CPUs, a signal processing circuit for analog signals read from a plurality of magnetic heads, a system on a chip (SoC) in which a host interface circuit and the like are incorporated, a storage device such as a DRAM, a motor driver IC that drives a spindle motor and a voice coil motor, and the like.

Further, the flexible board is mounted with a preamplifier IC that connects a magnetic head and performs writing and reading of data by the magnetic head.

In addition, the flexible board is required to have good flexibility, durability, cleanliness without discharging dust, and the like with respect to repeated bending operation by seeking of the HDD operating at high speed.

In recent years, in order to realize a further increase in the capacity of the HDD, from the viewpoint of an increase in the number of magnetic disks and the number of magnetic heads and incorporation of techniques such as two dimensional magnetic recording (TDMR) and microwave assisted magnetic recording (MAMR), it is desired to secure a desired solder bump height in response to a narrowing pitch while further suppressing a short circuit between adjacent solder bumps and reducing the amount of solder to be used.

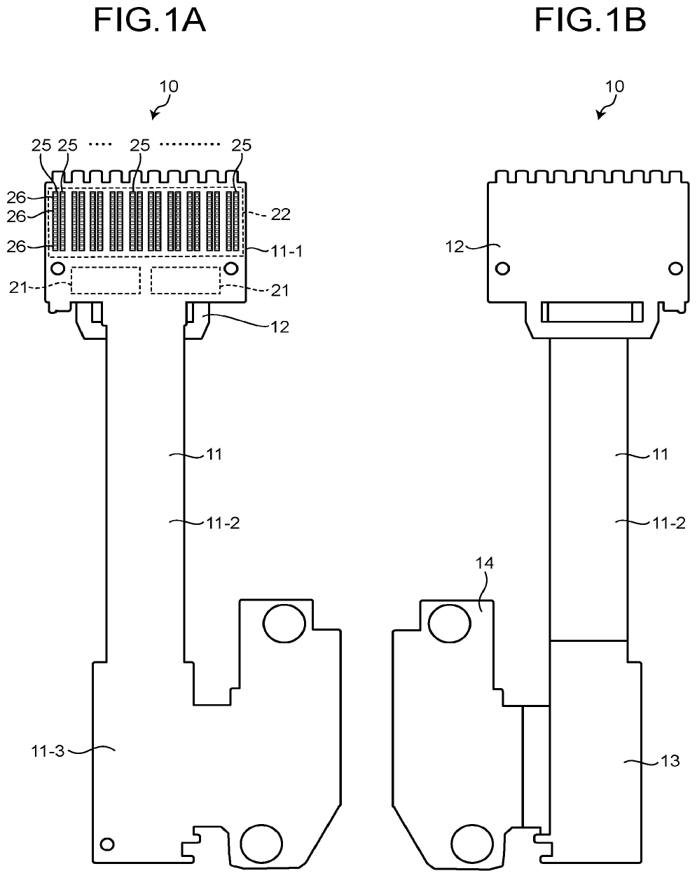

FIGS. 1A and 1B are explanatory diagrams of a flexible board assembly for an HDD according to the embodiment.

FIG. 1A is a front view of the flexible board assembly. FIG. 1B is a rear view of the flexible board assembly.

The flexible board assembly 10 includes a flexible board 11, a first support plate 12, a second support plate 13, and a third support plate 14.

In this configuration, the first support plate 12 is fixed at a predetermined position in the vicinity of a magnetic head in a housing of an HDD device. In addition, the second support plate 13 is disposed at a predetermined position in the housing of the HDD device, and the third support plate 14 is fixed at a predetermined position in the vicinity of a controller board or the like of the HDD device.

The flexible board 11 includes a head portion 11-1, a wiring pattern portion 11-2, and a base portion 11-3.

The head portion 11-1 includes an amplifier connection terminal portion 21 in which a preamplifier IC is disposed, and a solder bump forming portion 22 in which a plurality of solder bumps to which terminal groups of connection cables of a plurality of the magnetic heads are connected are formed.

More specifically, the solder bump forming portion 22 includes terminal groups 25 corresponding to the number (20 in the example of FIG. 1A) of connectable magnetic heads. In the example of FIG. 1A, the terminal groups 25 extend in the vertical direction, and each terminal group 25 has solder bump portions (terminal portions) 26 as many as the number of functions of the magnetic head.

For example, each terminal group 25 includes 10 solder bump portions 26.

In the wiring pattern portion 11-2, a wiring pattern (not illustrated) formed of copper foil is disposed to be covered with a cover lay film, and electrically connects a wiring pattern of the head portion 11-1 and a wiring pattern of the base portion 11-3.

In the base portion 11-3, a connection terminal (not illustrated) or the like to the controller board or the like of the HDD device is disposed.

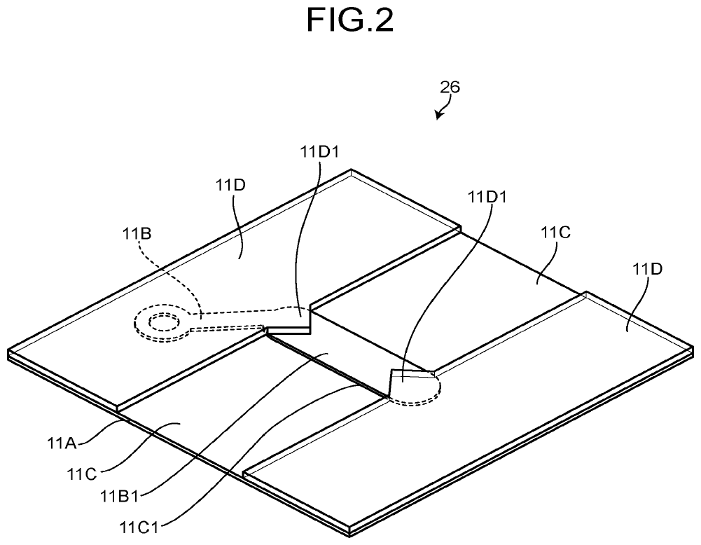

FIG. 2 is a schematic external perspective view of the solder bump portion.

As illustrated in FIG. 1A, the solder bump portion 26 is formed on the flexible board 11.

Specifically, the solder bump portion 26 is provided with a base material 11A constituting the flexible board 11, and a wiring pattern 11B formed of copper foil or the like on the base material 11A.

As a material of the base material 11A, a resin film such as a polyimide film or a PET film is used.

A base film 11C as an insulating member is provided on the base material 11A.

The base film 11C covers the base material 11A and the wiring pattern 11B, and an opening 11C1 is formed corresponding to a bump forming portion 11B1 of the wiring pattern 11B.

As a material of the base film 11C, a resin film such as a polyimide film or a PET film is used.

For the wiring pattern 11B, for example, a copper thin film is used as a conductor.

Further, a portion of the wiring pattern 11B excluding the opening 11C1 and a part of the base film 11C include a cover lay film 11D formed of a material having a solder contact angle larger than that of the bump forming portion 11B1 (a material having solder wettability lower than that of the bump forming portion 11B1), that is, a material having a contact angle larger (having lower wettability) than that of the material of the wiring pattern 11B, and the cover lay film 11D functions as a covering portion 11D1 covering a part of the bump forming portion 11B1.

In FIG. 2, the bump forming portion 11B1 has a rectangular shape in plan view. In addition, a part of the cover lay film 11D functions as the covering portion 11D1 and is provided at both ends (an upper left portion and a lower right portion of the bump forming portion 11B1 in the example of FIG. 2) of the bump forming portion 11B1 in the longitudinal direction.

Further, the covering portion 11D1 has a protruding shape from the both ends of the bump forming portion 11B1 in the longitudinal direction toward a central portion of the bump forming portion 11B1.

In the example of FIG. 2, the planar shape of the covering portion 11D1 is triangular.

As a forming method of the covering portion 11D1, the covering portion 11D1 is formed by punching the cover lay film 11D and cutting the cover lay film 11D with a cutter before the cover lay film 11D is attached. Alternatively, the cover lay film is formed by cutting the cover lay film with a laser cutter device.

Here, the planar shape of the covering portion 11D1 only needs to have the protruding shapes protruding from the both ends of the bump forming portion 11B1 in the longitudinal direction toward the central portion of the bump forming portion 11B1, and is not limited to a triangle as illustrated in FIG. 2, and various shapes such as a polygonal shape, a semicircular shape, or a semi-elliptical shape can be adopted.

In addition, in the above description, the covering portion 11D1 is formed integrally with the cover lay film 11D, which is an insulating member. However, the covering portion 11D1 may be configured separately from the cover lay film 11D using a material having a larger contact angle (lower wettability) with respect to solder than that of the wiring pattern 11B and different from or the same as the cover lay film 11D, which is an insulating member.

Here, the formation of the solder bump will be described.

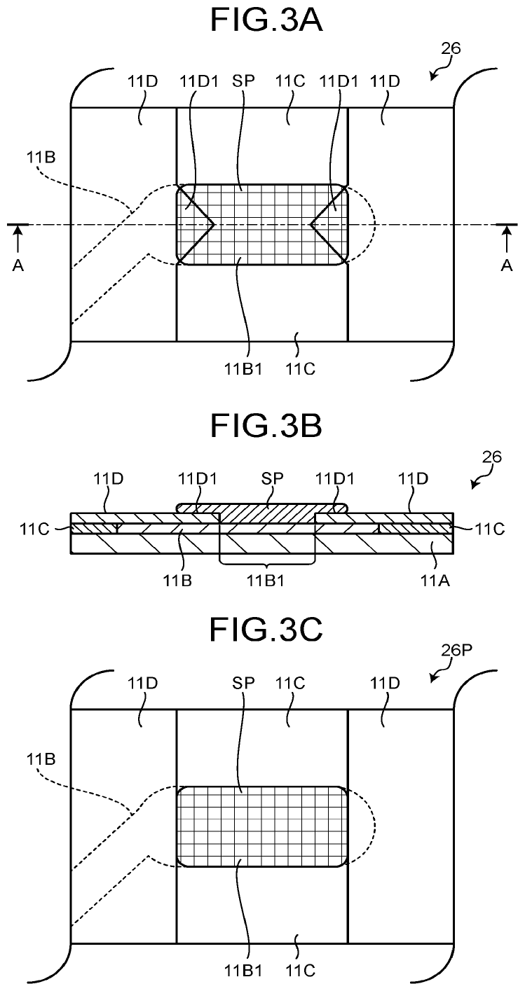

FIGS. 3A to 3C are explanatory diagrams (part 1) of solder bump formation.

FIG. 3A is a plan view at the time of applying solder paste in solder bump formation according to the embodiment, and FIG. 3B is a cross-sectional view taken along line A-A of FIG. 3A. In addition, FIG. 3C is a plan view at the time of applying solder paste in conventional solder bump formation.

The formation of solder bump is performed by a screen printing method.

More specifically, solder paste SP is supplied to a metal mask (print mask), and the mask is pulled up to form the solder paste SP on the bump forming portion 11B1 of the flexible board 11 as illustrated in FIGS. 3A and 3B.

In this case, the solder paste SP is applied onto the covering portion 11D1 in a portion where the covering portion 11D1 is formed as illustrated in FIG. 3B, which is different from a conventional case where the solder paste SP is applied to the entire region on the wiring pattern constituting the bump forming portion 11B1 as illustrated in FIG. 3C.

Then, solder bumps are formed using a reflow furnace.

In this case, examples of a heating method in the reflow furnace include hot air heating, infrared ray heating, and steam heating, and it is also possible to combine a plurality of heating methods in order to maintain uniformity of the temperature in the furnace and prevent excessive temperature rise.

More specifically, in the reflow furnace, preheating is performed in which the temperature is raised while volatilizing a solvent contained in the solder paste, and flux (solder auxiliary) is maintained at a constant temperature at which it is easy to activate the flux.

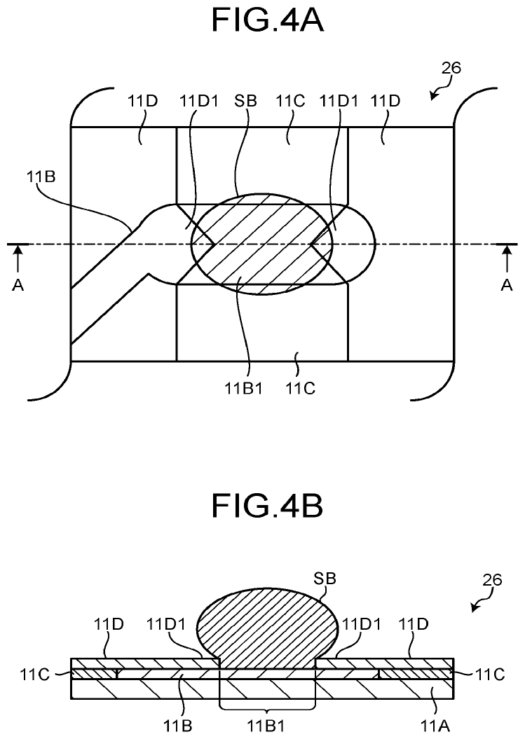

FIGS. 4A and 4B are explanatory diagrams (part 2) of solder bump formation.

FIG. 4A is a plan view at the time of forming the solder bump portion according to the embodiment, and FIG. 4B is a cross-sectional view taken along line A-A of FIG. 4A.

After the preheating, main heating is performed in which the temperature is raised until the solder is melted while the temperature of the flexible board and the temperature of a mounted component are uniformly raised.

As a result, the solder paste SP is completely liquefied, and the liquefied solder gradually becomes spherical due to surface tension.

In this case, as described in FIG. 3C, since the solder paste SP is conventionally applied to the entire region on the wiring pattern constituting the bump forming portion 11B1, the contact angle with respect to the solder in the region to which the solder paste SP is applied is the same, so that the solder bump is simply formed according to the solder contact angle of the wiring pattern constituting the bump forming portion 11B1.

On the other hand, according to the embodiment, since the contact angle of the covering portion 11D1, which is a part of the cover lay film 11D, is larger than the contact angle of the wiring pattern 11B, more solder is repelled when the solder paste SP applied to the covering portion 11D1 is melted.

That is, the molten solder moves to the central portion of the bump forming portion 11B1 and thus to the upper side of the bump forming portion 11B1, so that when the amount of solder paste SP is the same, the height of the solder bump SB is formed higher as compared with a case where the covering portion 11D1 is not provided.

In this case, if the height of the solder bump SB is made the same as a conventional height, the amount of solder to be used can be made smaller than that in the conventional solder bump forming method.

Then, after the solder bump is formed in a desired shape, cooling is performed by blowing air.

Further, when the formation of the solder bump is completed, it is not preferable that flux residues remain on the flexible board from the viewpoint of reliability, and thus flux cleaning for removing the flux is performed.

As a result, it is possible to form a solder bump capable of reducing the amount of solder used and securing a desired solder bump height while responding to the narrowing of the pitch of the solder bump.

Although the above description is a qualitative description of the formation of the solder bump, the effects of the embodiment will be described more specifically.

In the following, in order to describe the effects of the embodiment, results of performing simulations for solder bump formation will be described.

In this case, a simulation model used is as follows.

The composition of solder was Sn-3.0Ag-0.5Cu.

The density of the solder was 7400 (g/m³).

The surface tension of the solder was 500 (mN/m).

The thickness of solder paste was 108.5 μm, and the transfer rate thereof was 100%.

The thickness of a wiring pattern (conductive material) was 12 μm, and the contact angle thereof was 10 (deg.).

The thickness of a cover lay film was 12.5 μm, and the contact angle thereof was 160 (deg.).

The thickness of a base film was 12.5 μm, and the contact angle thereof was 160 (deg.).

The thickness of an adhesive layer was 15 μm, and the contact angle thereof was 160 (deg.).

### First Simulation

First, a simulation (first simulation) was performed as to whether or not the method of the embodiment can form a solder bump having a higher height than that of a conventional example in the case of the same mounting area of solder bumps.

In the first simulation, the shape of a conventional (comparative) solder bump forming portion was a rectangular shape as illustrated in FIG. 3C, the dimension was 0.1463 mm×0.382 mm, and the area thereof was 0.0559 mm².

In addition, as illustrated in FIG. 3A, the shape of a solder bump forming portion of the embodiment was a shape in which both ends of the rectangular shape in the longitudinal direction were cut out with isosceles triangles corresponding to the covering portions (an hourglass drum shape in which short bases of two trapezoids having the same shape were abutted), the length of a long base of the trapezoid was 0.450 mm, the height (cut-away height) of the isosceles triangle was 0.068 mm, and the area thereof was 0.0559 mm².

The solder bumps obtained as simulation results were as follows.

### Conventional Solder Bump

Volume of metal solder: 9.766×10⁻¹² mm³
Bump height: 188 μm
Bump width: 243 μm

### Solder Bump of Embodiment

Volume of metal solder: 9.753×10⁻¹² mm³
Bump height: 191 μm
Bump width: 244 μm

That is, according to the embodiment, it is possible to form the solder bump having a height higher than that in the conventional solder bump forming method with the same mounting area.

### Second Simulation

In the first simulation, the shape of the covering portion is a triangular shape, but in a second simulation, the shape of the covering portion is a semicircular shape.

In the second simulation, the shape of a conventional (comparative) solder bump forming portion was a rectangular shape, the dimension was 0.1463 mm×0.396 mm, and the area thereof was 0.058 mm².

In addition, the shape of a solder bump forming portion of the embodiment was a shape (spool shape) obtained by cutting out a semicircle corresponding to the covering portion at both ends of the rectangular shape in the longitudinal direction, the length of a base of the solder bump forming portion was 0.450 mm, the radius (cut-away height) of the semicircle was 0.038 mm, and the area thereof was 0.058 mm².

The solder bumps obtained as simulation results were as follows.

### Conventional Solder Bump

Volume of metal solder: 9.817×10⁻¹² mm³
Bump height: 183 μm
Bump width: 240 μm

### Solder Bump of Embodiment

Volume of metal solder: 9.800×10⁻¹² mm³
Bump height: 186 μm
Bump width: 242 μm

That is, according to the embodiment, it can be seen that the solder bump having a height higher than that in the conventional solder bump forming method can be formed with the same mounting area.

As described above, according to the present embodiment, it is possible to provide a board and an electronic device capable of reducing the amount of solder used and securing a desired solder bump height while responding to the narrowing of the pitch of solder bumps.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A board comprising:
a base material;
a wiring pattern provided on the base material;
an insulating member covering the base material and the wiring pattern, and having an opening corresponding to a bump forming portion of the wiring pattern; and
a covering portion formed of a material having a solder contact angle larger than that of the bump forming portion in the opening, and covering a part of the bump forming portion.

2. The board according to claim 1, wherein
the bump forming portion has a rectangular shape, and
the covering portion is provided at both ends of the bump forming portion in a longitudinal direction.

3. The board according to claim 2, wherein
the covering portion has protruding shapes from the ends toward a central portion of the bump forming portion.

4. The board according to claim 3, wherein
a planar shape of a portion of the covering portion covering the bump forming portion is triangular, polygonal, or semicircular.

5. The board according to claim 1, wherein
the covering portion is made of a material identical to the insulating member and is formed integrally with the insulating member.

6. The board according to claim 1, wherein
the covering portion is formed of a material different from the insulating member.

7. An electronic device comprising:
the board according to claim 1; and
an electronic component connected to a solder bump formed in the bump forming portion.
